(19) United States
(12) Patent Application Publication
(10) Pub. No.: US 2012/0006395 A1
(43) Pub. Date: Jan. 12, 2012

(54) COATED STAINLESS STEEL SUBSTRATE

(75) Inventors: Salah Boussaad, Wilmington, DE (US); Juan Carlos Figueroa, Wilmington, DE (US); Kenneth C. Keup, Newark, DE (US); Damien Francis Reardon, Wilmington, DE (US)

(73) Assignee: E. I. DU PONT DE NEMOURS AND COMPANY, Wilmington, DE (US)

(21) Appl. No.: 12/832,315

(22) Filed: Jul. 8, 2010

(51) Int. Cl. H01L 31/0224; B05D 1/38; B05D 3/02; B05D 7/00; B32B 15/04; B32B 17/06

(52) U.S. Cl. 136/256; 428/630; 428/623; 427/258

(57) ABSTRACT

The present disclosure relates to a method of manufacturing of a metal oxide and glass coated metal product. This invention also relates to a coated metallic substrate material that is suitable for manufacturing flexible solar cells and other articles in which a passivated stainless steel surface is desirable.

### FIELD OF THE INVENTION

The present disclosure relates to a method of manufacturing a metal oxide and glass coated metal product. This invention also relates to a coated metallic substrate material that is suitable for manufacturing flexible solar cells and other articles in which a passivated stainless steel surface is desirable.

### BACKGROUND

Photovoltaic cells are made by depositing various layers of materials on a substrate. The substrate can be rigid (e.g., glass or a silicon wafer) or flexible (e.g., a metal or polymer sheet).

The most common substrate material used in the manufacture of thin film Cu(In, Ga)Se₂ (CIGS) solar cells is soda lime glass. Soda lime glass contributes to the efficiency of the solar cell, due to the diffusion of an alkali metal (primarily sodium) from the glass into the CIGS layer. However, batch production of CIGS on glass substrates is expensive and glass is typically too rigid to be adapted to a roll-to-roll process. The disadvantages of using common glass substrates for the photovoltaic cells have motivated the search for substrates that are flexible, tolerant of the high temperatures used to create the photoactive layers, inexpensive and suitable for use in roll-to-roll processes.

Several materials have been tested as substrate materials for flexible CIGS solar cells, including polymers such as polyimide and metals such as molybdenum, aluminum and titanium foils. The substrate should be tolerant of temperatures up to 700° C. and reducing atmospheres. A metallic substrate must also be electrically insulated from the back contact to facilitate production of CIGS modules with integrated series connections. It is desirable for the coefficient of thermal expansion (CTE) of the substrate material to be as close as possible to the CTE of the electrical insulating material to avoid thermal cracking or delamination of the insulating material from the substrate.

CZTS-Se based solar cells are known, and are analogous to CIGS solar cells except that CIGS is replaced by CZTS-Se, where “CZTS-Se” encompass all possible combinations of Cu₂ZnSn(S, Se)₄, including Cu₂ZnSnS₄, Cu₂ZnSnSe₄, and

Cu₂ZnSnSₓSe₍₄₋ₓ₎, where 0≦x≦4.

Since polymers are generally not thermally stable above 500° C., the focus has generally been on developing coated metal substrates.

Deposition of SiOₓ or SiO₂ layers onto metal strips in batch-type deposition processes is known.

It is also known to coat a metallic base with a first coat of an alkali silicate, optionally containing alumina particles. A second coat of silicone can be applied onto the first coat of an alkali silicate.

In another approach, a stainless steel plate is contacted with a solution of a metal alkoxide, an organoalkoxysilane, water, and thickeners such as alkoxy silane in an organic solvent, then dried and calcined.

A method for producing a substrate for solar batteries has also been disclosed in which a first insulating layer is formed on a metal plate (e.g., a stainless steel plate). Then the surface of the metal plate exposed by pinholes in the first insulating layer is oxidized by heating the metal plate in air. A second insulating layer is then applied over the first insulating layer.

A coated steel substrate useful as a substrate for flexible CIGS solar cells has been disclosed that comprises a stainless steel strip coated with a sodium-doped alumina layer onto which an electrically conducting layer of molybdenum has been deposited.

A process for forming an electrically insulating layer of aluminum oxide on ferritic stainless steel has been disclosed. The alumina-coated stainless steel sheet was used as a substrate for an amorphous silicon solar battery manufactured by P-CVD (plasma chemical vapor deposition) on the oxide film.

However, there remains a need for process to produce a substrate that has the flexibility of a metal, the surface properties of glass, and can be used in a roll-to-roll process for the manufacture of CIGS cells.

### SUMMARY

One aspect of this invention is a process comprising:
a) depositing a glass precursor on at least a portion of an alumina-coated stainless steel substrate; and
b) heating the glass precursor to form a glass layer on at least a portion of the alumina-coated stainless steel substrate, wherein the glass layer comprises SiO₂, Al₂O₃, Na₂O, and B₂O₃, and optionally an oxide selected from the group consisting of MgO, K₂O, CaO, PbO, GeO₄, SnO₂, Sb₂O₃ and Bi₂O₃.

Another aspect of this invention is a multi-layer article comprising:
a) a stainless steel substrate comprising 0.1 to 10 wt % aluminum;
b) an alumina coating disposed on at least a portion of the stainless steel substrate; and
c) a glass layer disposed on at least a portion of the alumina coating, wherein the glass layer comprises SiO₂, Al₂O₃, Na₂O, and B₂O₃ and optionally an oxide selected from the group consisting of MgO, K₂O, CaO, PbO, GeO₄, SnO₂, Sb₂O₃ and Bi₂O₃.

### DETAILED DESCRIPTION

One aspect of this invention is a process comprising the steps:
a) depositing a glass precursor on at least a portion of the surface of an alumina-coated stainless steel substrate; and
b) heating the glass precursor to form a glass layer on at least a portion of the alumina-coated stainless steel substrate, wherein the glass layer comprises SiO₂, Al₂O₃, Na₂O, and B₂O₃, and optionally an oxide selected from the group consisting of MgO, K₂O, CaO, PbO, GeO₄, SnO₂, Sb₂O₃ and Bi₂O₃.

This process is useful for passivating a surface of the stainless steel substrate. The passivation may protect the surface from chemical attack. The alumina coating and glass layer may also serve as thermal and/or electrical insulating layers.

This process can be conducted batch-wise or as a continuous process, e.g., in a roll-to-roll process.

### Stainless Steel Substrate

Suitable stainless steel substrates can be in the form of sheets, foils or other shapes. Sheets and foils are preferred for roll-to-roll processes. Suitable stainless steel typically comprises: 13-22 wt % chromium; 1.0-10 wt % aluminum; less than 2.1 wt % manganese; less than 1.1 wt % silicon; less than 0.13 wt % carbon; less than 10.6 wt % nickel; less than 3.6 wt % copper; less than 2 wt % titanium; less than 0.6 wt % molybdenum; less than 0.15 wt % nitrogen; less than 0.05 wt % phosphorus; less than 0.04 wt % sulfur; and less than 0.04 wt % niobium, wherein the balance is iron.

In some embodiments, the stainless steel comprises: about 13 wt % chromium; 3.0-3.95 wt % aluminum; less than 1.4 wt % titanium; about 0.35 wt % manganese; about 0.3 wt % silicon; and about 0.025 wt % carbon, wherein the balance is iron.

In some embodiments, the stainless steel comprises: about 22 wt % chromium and about 5.8 wt % aluminum, wherein the balance is iron.

For the purposes of the present invention, quantities of any component that are so small that they cannot be measured quantitatively by known and/or conventional methods are not considered to be within the scope of the present invention and, therefore, when only an upper compositional range limit is provided it should be understood to mean that the lower limit is any quantity measureable by known or conventional means.

### Alumina-Coated Stainless Steel Substrate

A suitable alumina-coated stainless steel substrate can be prepared by annealing a stainless steel sheet, foil or article that has a composition as described above. The annealing is typically carried out in an oxygen-containing atmosphere at a temperature between 800 and 1000° C. for at least 15 hr, or between 1000 and 1100° C. for at least 9 hr, or between 1100 and 1200° C. for at least 6 hr. A suitable thickness of the alumina layer formed by the annealing process is typically about 0.001 to about 1.000 microns.

Depending on the initial composition of the stainless steel, other elements may also migrate to the surface during the annealing and form islands of metal oxides (e.g., titanium oxide, iron oxide and/or chromium oxide) on the surface of the alumina-coated stainless steel. As used herein, the alumina layer is understood to both the alumina and the islands of other metal oxides.

### Glass Precursor Layer

In one aspect of this invention, the alumina layer of the alumina-coated stainless steel substrate is further coated with a glass precursor layer, followed by steps of drying and firing the glass precursor layer to form a glass layer on the stainless steel substrate. As described below, the thickness of the glass layer can be increased by carrying out multiple cycles of coating-and-drying before firing, or by carrying out several cycles of coating-drying-and-firing.

The glass layer is formed by coating an alumina-coated stainless steel substrate with a glass precursor composition. The precursor composition typically contains: a soluble form of silicon, (e.g., silicon tetraacetate, silicon tetrapropionate, bis(acetylacetonato) bis(acetato) silicon, bis(2-methoxyethoxy) bis (acetato) silicon, bis(acetylacetonato) bis(ethoxy) silicon, tetramethylorthosilicate, tetraethylorthosilicate, tetraisopropylorthosilicate, or mixtures thereof), dissolved in a minimum amount of a C1-C10 alcohol (e.g., methanol, ethanol, 1-propanol, 2-propanol, 1-butanol, 2-butanol, isomers of 1-butanol, 1-pentanol, 2-pentanol, 3-pentanol, isomers of pentanol, 1-hexanol, 2-hexanol, 3-hexanol, isomers of hexanol, 1-heptanol, isomers of heptanol, 1-octanol, isomers of octanol, 1-nonanol, isomers of nonanol, 1-decanol, isomers of decanol, ethylene glycol, 1-methoxyethanol, 1-ethoxyethanol, or mixtures thereof); a trialkylborate (e.g., trimethylborate, triethylborate, tripropylborate, trimethoxyboroxine, or mixtures thereof); a sodium salt (e.g., sodium acetate, sodium propionate, sodium silicate, sodium alkoxides, or mixtures thereof); optionally, a potassium salt (e.g., potassium acetate, potassium propionate, potassium methoxide, potassium ethoxide, potassium isopropoxide, or mixtures thereof); and an aluminum compound (e.g., tris(acetylacetonato) aluminium, aluminium methoxide, aluminium ethoxide, aluminium isopropoxide, aluminium n-propoxide, or mixtures thereof). In some embodiments, the glass precursor formulation is filtered prior to coating the stainless steel substrate. In some embodiments, the composition of the glass precursors in the formulation is in a ratio of about 100 to 27 to 12 to 3 to 3 with respect to the elements: Si, B, Na, K, and Al.

In one embodiment, the precursor composition is prepared by dissolving a silicon oxide precursor (e.g., silicon tetraacetate) in a minimum amount of 1-butanol, or a 1:1 mixture of 1-butanol and propionic acid, and stirring. To this solution, an aluminium oxide precursor (e.g., tris(acetylacetonato)aluminium), a boron oxide precursor (e.g., triethyl borate), a sodium oxide precursor (e.g., sodium acetate) and a potassium oxide precursor (e.g., potassium propionate) are added. Once the precursors are dissolved, more solvent is added to obtain the desired concentration.

Suitable precursors for MgO, K₂O, CaO, PbO, GeO₄, SnO₂, Sb₂O₃ and Bi₂O₃ include the respective acetates: potassium acetate, calcium acetate, lead acetate, germanium acetate, tin acetate, antimony acetate, and bismuth acetate.

Silicon alkoxides (e.g., silicon tetraorthosilicate) and aluminum alkoxides (e.g., aluminum isopropoxide) can also be used to prepare the glass precursor compositions. However, these materials hydrolyze in the presence of water, so they should be stored under anhydrous conditions.

Optionally, borosilicate glass nanoparticles can be added to the formulation.

### Coating, Drying and Firing

Coating the glass precursor composition onto the alumina-coated stainless steel substrate can be carried out by any conventional means, including bar-coating, spray-coating, dip-coating, microgravure coating, or slot-die coating.

After coating the glass precursor composition onto the alumina-coated stainless steel substrate, the precursor is typically dried in air at 100 to 150° C. to remove solvent. In some embodiments, the dried glass precursor layer is then fired in air or an oxygen-containing atmosphere at 250 to 800° C. to convert the glass precursor layer to a fired glass layer.

In some embodiments, additional cycles of coating and drying are carried out prior to firing. This increases the thickness of the fired glass layer.

In some embodiments, the steps of coating, drying, and firing are repeated 2 or more times. This can also increase the total thickness of the fired glass layer. Multiple intermediate firing steps facilitate removal of any carbon that might be present in the glass precursor components.

In some embodiments, water is added to the precursor mixture prior to the coating step. This increases the viscosity of the glass precursor composition and facilitates the formation of glass layers of 50 nm to 2 microns thickness in one coating and drying cycle.

Both the firing step(s) and drying step(s) are typically conducted in air to ensure complete oxidation of the glass precursors. The presence of elemental carbon, carbonate intermediates or reduced metal oxides in the glass layer may lower the breakdown voltage of the insulating layer.

### Glass Layer

After firing, the glass layer typically comprises: greater than 70 wt % silica; less than 10 wt % alumina; 5-15 wt % of a boron oxide; and less than 10 wt % of oxides of sodium and/or potassium. In one embodiment, the fired glass layer comprises: about 81 wt % SiO₂, about 13 wt % B₂O₃, about 4 wt % Na₂O, and about 2 wt % Al₂O₃.

In some embodiments, the glass precursor compositions are selected to provide coefficients of linear thermal expansion of the glass layers to be close to those of the Mo and CIGS (or CZTS-Se) layers to reduce stress on the Mo and CIGS (or CZTS-Se) layers and to reduce film curling. In some embodiments, the CTE of the borosilicate glass is about 3.25×10⁻⁶/° C. to provide a good match to the CTE of the Mo layer (about 4.8×10⁻⁶/° C.) and the CIGS layer (about 9×10⁻⁶/° C.).

### Device

One aspect of this invention is a multi-layer article comprising:
a) a stainless steel substrate comprising 1 to 10 wt % aluminum;
b) an alumina coating disposed on at least a portion of the stainless steel substrate; and
c) a glass layer disposed on at least a portion of the alumina coating, wherein the glass layer comprises SiO₂, Al₂O₃, Na₂O, B₂O₃, and optionally an oxide selected from the group consisting of MgO, K₂O, CaO, PbO, GeO₄, SnO₂, Sb₂O₃ and Bi₂O₃.

The stainless steel substrate, alumina coating and glass layer are as described above.

This multilayer article can be used as the substrate for the manufacture of electronic devices. Such multilayer articles can also be used in medical devices.

In some embodiments, the multilayer article further comprises:
d) a conductive layer disposed on at least a portion of the glass layer.

In some embodiments, the multilayer article further comprises:
e) a photoactive layer disposed on the conductive layer;
f) a CdS layer disposed on the photoactive layer; and
g) a transparent conductive oxide disposed on the CdS layer.

Such multilayer articles can be used in photovoltaic cells.

Suitable conductive layers comprise materials selected from the group consisting of metals, oxide-doped metals, metal oxides, organic conductors, and combinations thereof. A conductive metal layer can be deposited onto the glass layer through a vapor deposition process or electroless plating. Suitable metals include Mo, Ni, Cu, Ag, Au, Rh, Pd and Pt. The conductive metal layer is typically 200 nm-1 micron thick. In one embodiment, the conductive material is molybdenum oxide-doped molybdenum.

In some embodiments, the multilayer article comprises organic functional layers, e.g., organic conductors such as polyaniline and polythiophene. In such embodiments, the multilayer article is generally not heated above 450° C., or 400° C., or 350° C., or 300° C., or 250° C., or 200° C., or 150° C., or 100° C. after the organic functional layer has been deposited.

Suitable photoactive layers include CIS (copper-indium-selenide), CIGS, and CZTS-Se.

The CIGS and CIS layers can be formed by evaporating or sputtering copper, indium and optionally gallium sequentially or simultaneously, then reacting the resulting film with selenium vapor. Alternatively, a suspension of metal oxide particles in an ink can be deposited on the conductive layer using a wide variety of printing methods, including screen printing and ink jet printing. This produces a porous film, which is then densified and reduced in a thermal process to form the CIGS or CIS layer.

CZTS-Se thin films can be made by several methods, including thermal evaporation, sputtering, hybrid sputtering, pulsed laser deposition, electron beam evaporation, photochemical deposition, and electrochemical deposition. CZTS thin-films can also be made by the spray pyrolysis of a solution containing metal salts, typically CuCl, ZnCl₂, and SnCl₄, using thiourea as the sulfur source.

The CdS layer can be deposited by chemical bath deposition.

A suitable transparent conductive oxide layer, such as doped zinc oxide or indium tin oxide, can be deposited onto the CdS layer by sputtering or pulsed layer deposition.

### EXAMPLES

### General

### Preparation Of Alumina-Coated Stainless Steel Foils For Examples 1-3:

A 50.8 micrometer thick stainless steel foil (Ohmaloy® 30, 2-3 wt % aluminum, ATI Allegheny Ludlum) was annealed at 1000° C. in air for 15 hr to provide a coating of alumina on the surface of the stainless steel foil.

The foil was then diced to size and argon plasma-cleaned (A.G. Services PE-PECVD System 1000) for 30 sec under the following conditions:

power=24.3 W

pressure=100.0 mTorr

throttle pressure=200.0 mTorr

argon gas flow=10.0 sccm

### Preparation of a Precursor Composition Containing 0.2 M [Si]:

Silicon tetraacetate (3.6695 g, 13.89 mmol) was dissolved in 1-butanol (60.00 ml) containing 0.25 ml of deionized water. To this solution, was added triethylborate (0.5616 g, 3.85 mmol), sodium acetate (0.1721 g, 1.79 mmol), potassium propionate (0.0429 g, 0.44 mmol) and tris(acetylacetonato) aluminum (0.1311 g, 0.40 mmol). The solution was stirred and 1-butanol was added until a total volume of 100.00 ml was achieved. The glass precursor composition was filtered through a 2 micron filter prior to coating the stainless steel substrate.

### Rod-Coating:

The substrates were rod-coated using a #20 bar on a Cheminstrument® motorized drawdown coater at room temperature in a clean room environment (class 100). The coated substrate was then dried at 150° C. for 1 min to form a dried glass precursor layer on the annealed stainless steel substrate. This procedure was used one or more times in each of the examples described below.

### Firing:

After drying, the coated substrates were fired to 600° C. for 30 min at a ramp rate of 8° C./s using a modified Leyboldt L560 vacuum chamber outfitted with cooled quartz lamp heaters above and below the coated substrate, with an air bleed of 20 sccm (total pressure 1 mTorr). Out-gassing was monitored using a residual gas analyzer. This procedure was used one or more times in each of the examples described below.

### Determination of Dielectric Strength:

Breakdown voltage was measured with a Vitrek 944i dielectric analyzer (San Diego, Calif.). The sample was sandwiched between 2 electrodes, a fixed stainless steel rod as cathode (6.35 mm diameter and 12.7 mm long) and a vertically sliding stainless steel rod as anode (6.35 mm diameter and 100 mm long). The mass of the sliding electrode (32.2 g) produced enough pressure so the anode and cathode form good electrical contact with the sample. The voltage was ramped at 100 V/s to 250 V and kept constant for 30 sec to determine the breakdown voltage and the sustained time. The thickness was measured using a digital linear drop gauge from ONO SOKKI, model EG-225. Dielectric strength can be calculated as the breakdown voltage per unit of thickness.

### EXAMPLE 1

### One Firing of Multiple Layers

The filtered glass precursor composition (0.1 ml) was rod-coated onto an annealed, plasma-cleaned stainless steel substrate and dried, as described above.

The drawdown coating and drying cycle was repeated five times. The substrate was then fired, as described above.

Breakdown voltage was found to be 520-600 V DC at 10 randomly selected locations.

After firing, a 200 nm Mo coating was deposited on the fired glass layer via sputter vapor deposition.

### EXAMPLE 2

### Deposition of a Single Layer Which is then Fired, Followed by Deposition of Subsequent Layers Which are then Fired

The filtered glass precursor composition (0.1 ml) was rod-coated onto an annealed, plasma-cleaned stainless steel substrate and dried, as described above.

This layer was then fired as described above.

The drawdown coating and drying cycle was repeated under the same conditions five times. The coated substrate was fired a second time, and then a 200 nm Mo layer was deposited on the fired glass layer via sputter vapor deposition.

### EXAMPLE 3

### Multiple Firing Process

The filtered glass precursor composition (0.1 ml) was rod-coated onto an annealed, plasma-cleaned stainless steel substrate and dried, as described above.

This layer was then fired as described above.

The cycle of coating, drying and firing steps was repeated five times.

A 200 nm Mo top electrode was deposited onto the fired glass layer via sputter vapor deposition.

### COMPARATIVE EXAMPLE A

### Borosilicate Glass Coating Directly on Stainless Steel

This example demonstrates that a coating of a borosilicate glass alone on a stainless steel substrate leads to lower breakdown voltages.

A 50.8 micrometer thick stainless steel foil (stainless steel 430, ATI Allegheny Ludlum) was diced to size and argon plasma-cleaned (A.G. Services PE-PECVD System 1000) for 30 sec under the following conditions:

power=24.3 W

pressure=100.0 mTorr

throttle pressure=200.0 mTorr

argon gas flow=10.0 sccm

This stainless steel substrate is similar to that used in Examples 1-3, except that it contains less than 5 microgram/g of aluminum, and was not annealed before being coated with a glass precursor composition.

The filtered glass precursor formulation (0.1 ml) was rod-coated onto a plasma-cleaned stainless steel substrate and dried.

This layer was then fired as described above.

The cycle of coating, drying and firing steps was repeated five times.

The breakdown voltage was found to be variable and inconsistent over the top surface of the glass-coated stainless steel.

A 200 nm Mo top electrode was deposited onto the fired glass layer via sputter vapor deposition.

What is claimed is:

1. A multi-layer article comprising:
a) a stainless steel substrate comprising 0.1 to 10 wt % aluminum;
b) an alumina coating disposed on at least a portion of a surface of the stainless steel substrate; and
c) a glass layer disposed on at least a portion of a surface of the alumina coating, wherein the glass layer comprises SiO₂, Al₂O₃, Na₂O, and B₂O₃, and optionally an oxide selected from the group consisting of MgO, K₂O, CaO, PbO, GeO₄, SnO₂, Sb₂O₃ and Bi₂O₃ and mixtures thereof.

2. The multi-layer article of claim 1, further comprising:
d) a conductive layer disposed on at least a portion of a surface of the glass layer.

3. The multi-layer article of claim 2, wherein the conductive layer comprises material selected from the group consisting of metals, oxide-doped metals, metal oxides, organic conductors, and combinations thereof.

4. The multi-layer article of claim 3, wherein the conductive layer comprises molybdenum.

5. The multi-layer article of claim 1, wherein the stainless steel substrate is in the form of a sheet.

6. The multi-layer article of claim 1, wherein the stainless steel substrate comprises less than 2 wt % Ti.

7. The multi-layer article of claim 1, wherein the stainless steel substrate comprises less than 2.1 wt % Mn.

8. The multilayer article of claim 2, further comprising:
e) a photoactive layer disposed on the conductive layer;
f) a CdS layer disposed on the photoactive layer; and
g) a transparent conductive oxide disposed on the CdS layer.

9. The device of claim 8, wherein the photoactive layer comprises CIGS, CIS or CZTS-Se.

10. The device of claim 8, wherein the transparent conductive oxide is selected from the group consisting of doped zinc oxide and indium tin oxide.

11. A process comprising:
a) depositing a glass precursor on at least a portion of an alumina-coated stainless steel substrate; and
b) heating the glass precursor to form a glass layer on at least a portion of the alumina-coated stainless steel substrate, wherein the glass layer comprises SiO₂, Al₂O₃, Na₂O, and B₂O₃, and optionally an oxide selected from the group consisting of MgO, K₂O, CaO, PbO, GeO₄, SnO₂, Sb₂O₃ and Bi₂O₃.

12. The process of claim 11, further comprising drying the deposited glass precursor at 100 to 150° C. prior to heating the glass precursor at 250 to 800° C. to form a glass layer.

13. The process of claim 12, wherein the deposition and drying steps are repeated 2-5 times before the heating step.

14. The process of claim 12, further comprising:
c) depositing additional glass precursor on at least a portion of the glass layer; and
d) heating the additional glass precursor to form an additional glass layer on at least a portion of the glass layer, wherein the glass layers comprise SiO₂, Al₂O₃, Na₂O, and B₂O₃, and optionally an oxide selected from the group consisting of MgO, K₂O, CaO, PbO, GeO₄, SnO₂, Sb₂O₃ and Bi₂O₃.

15. The process of claim 11, wherein the glass precursor comprises:
a) a silicon alkoxide or carboxylate;
b) a C1-C10 alcohol;
c) a trialkylborate;
d) a sodium salt; and
e) an aluminum complex.

16. The process of claim 15, wherein the soluble form of silicon is selected from the group consisting of silicon tetraacetate, silicon tetrapropionate, bis(acetylacetonato) bis(acetato) silicon, bis(2-methoxyethoxy) bis (acetato) silicon, bis(acetylacetonato) bis(ethoxy) silicon, tetramethylorthosilicate, tetraethylorthosilicate, tetraisopropylorthosilicate, and mixtures thereof.

17. The process of claim 15, wherein the C1-C10 alcohol is selected from the group consisting of methanol, ethanol, 1-propanol, 2-propanol, 1-butanol, 2-butanol, isomers of 1-butanol, 1-pentanol, 2-pentanol, 3-pentanol, isomers of pentanol, 1-hexanol, 2-hexanol, 3-hexanol, isomers of hexanol, 1-heptanol, isomers of heptanol, 1-octanol, isomers of octanol, 1-nonanol, isomers of nonanol, 1-decanol, isomers of decanol, ethyleneglycol, 1-methoxyethanol, 1-ethoxyethanol, and mixtures thereof.

18. The process of claim 15, wherein:
the trialkylborate is selected from the group consisting of trimethylborate, triethylborate, tripropylborate, trimethoxyboroxine, and mixtures thereof);
the sodium salt is selected from the group consisting of sodium acetate, sodium propionate, sodium silicate, sodium alkoxides, and mixtures thereof;
the potassium salt is selected from the group consisting of potassium acetate, potassium propionate, potassium methoxide, potassium ethoxide, potassium isopropoxide, and mixtures thereof; and
the aluminum compound is selected from the group consisting of tris(acetylacetonato) aluminium, aluminium methoxide, aluminium ethoxide, aluminium isopropoxide, aluminium n-propoxide, and mixtures thereof.

19. The process of claim 15, wherein the glass precursor further comprises water.
